(19) United States
(12) Patent Application Publication
(10) Pub. No.: US 2002/0032489 A1
(43) Pub. Date: Mar. 14, 2002

(54) Transferring computer files and directories

(76) Inventors: Dermot Tynan, Aughinish (IE); Oliver Leahy, Galway (IE); Sean Doherty, Galway (IE); Morgan Doyle, Galway (IE)

Correspondence Address: Carol H. Peters, Mintz, Levin, Cohn, Ferris, Glovsky and Popeo, P.C, One Financial Center, Boston, MA, 02111, US

(21) Appl. No.: 09/853,380

(22) Filed: May 11, 2001

(30) Foreign Application Priority Data
Sep. 11, 2000 (IE) S2000/0725

(51) Int. Cl. G11C 5/00

(52) U.S. Cl. 700/1; 711/1

(57) ABSTRACT

A method for transferring one or more files is disclosed. The files are transferred from a host peer to a target peer in which respective message digests are calculated for a file on a host peer and a target peer. A comparison between the calculated digests is made prior to transmission of a file in order to establish whether the target peer possesses the file in question. Where it is found that the message digests are identical, it is assumed that the file is present on the target peer. This can be done in the event that it is suspected that a file to be transferred may already exist on the target peer, for example if the target peer already possesses a file of the same name as that to be transferred. If it is discovered that message digests calculated by the host peer and the target peer are identical, the file is not transmitted by the host peer, thereby preventing an unnecessary use of available bandwidth.

### FIELD OF THE INVENTION

The present invention relates to a method for transferring computer files, directories and directory structures. It has particular application to performing such transfers reliably and automatically between peers over a network, optionally including a wide area network such as the Internet.

### BACKGROUND OF THE INVENTION

This invention has application to situations in which a file or a plurality of files much be transferred between two computer systems (referred to generally as “peers”) that are interconnected for data transfer in a network. For convenience, a peer that contains a file or files to be transferred will be referred to as a “host peer”, and a peer that is intended to receive a file or files will be referred to as a “target peer”. Moreover, the term “network” should be understood to include a diverse range of installations that allow data to be transferred between two or more peers including, but not limited to, a local-area network (such as an Ethernet), a wide-area network (such as the Internet), wireless links (such as infra-red links), and any combination of the above-mentioned of other technologies.

Several methods are in use that allow for a peer to request the transfer of a file from a host to a target. For example, methods using the file transfer protocol (ftp) defined in IETF RFC959 are probably in most widespread use on the Internet. However, such existing methods typically require intervention of a user or a client application if unnecessary transfers are to be avoided or if the success or failure of a transfer is to be confirmed.

### SUMMARY OF THE INVENTION

It is an aim of this invention to provide a method for transferring files or directories from one peer to another which provides improved functionality as compared with known methods.

More particularly, it is an aim of this invention to provide a method for moving files and/or directory structures from a host peer to one or more target peers which includes one or more of the following properties:

the method may provide a guarantee that the file or files have been delivered successfully, so that a user or client application does not need to test that the file was received and initiate a resend;

the method can provide strong proof that the or each peer has received the file;

if the file is already on a target peer the host peer will not resend it;

if a connection is broken during the transfer of a file, the method will try to re-establish the connection and will not resend that part of the file that was already sent;

in suitable circumstances, a number of virtual streams can be used so that the available bandwidth can all be used;

a number of priority queues may be provided in order that user or client application can identify urgent content, whereby the method ensures that content receives more bandwidth than lower priority content; or

the method may allow a user or client application to define a prerequisite task that must be completed before a given task is started.

From a first aspect, the invention provides a method for transferring one or more files from a host peer to a target peer in which respective message digests are calculated for a file on a host peer and a target peer, and a comparison between the calculated digests is made in order to establish whether the target peer possesses the file in question.

Where it is found that the message digests are identical, it is assumed that the file is present on the target peer.

Message digests are commonly used cryptographic tools. They are at the heart of all the common Internet protocols that use cryptography, including SSL, which is used to encrypt traffic to and from web servers.

In preferred methods embodying the invention, the comparison is made prior to transmission of a file from the host peer to the target peer. This can be done in the event that it is suspected that a file to be transferred may already exist on the target peer, for example if the target peer already possesses a file of the same name as that to be transferred. If it is discovered that message digests calculated by the host peer and the target peer are identical, the file is not transmitted by the host peer, thereby preventing an unnecessary use of available bandwidth.

Embodiments according to the last-preceding paragraph are particularly advantageous in cases where a file or a set of files, or content set, is being sent to a group of target peers. As each target peer in the group receives the content it may try to send it to others in the group. In order that this does not result is a large amount of unnecessary network traffic, it is advantageous that each target peer can determine which of such transfers are unnecessary, and not proceed with them.

Additionally, in preferred embodiments of the invention, comparison of message digests may be made after a file has been sent to the target peer. In this case, if it is found that the message digests differ, it is assumed that an error has occurred during transmission of the file, so suitable remedial action can be taken. For example, the file, or a portion of the file, may be re-transmitted.

It is highly desirable that the possibility that an identical message digest could be generated by two different files be minimal. This minimises that the chance that a file will not be transmitted, when it should in fact be. Moreover, it is desirable that derivation of the file from the message digest should be a computationally impracticable task.

In preferred embodiments, the message digest is calculated by means of a hashing algorithm. A hashing algorithm can be used to calculate a ‘fingerprint’ of any binary stream, such as a file on a computer disc. Provided that a suitable algorithm is selected, it is conjectured and generally accepted that it is computationally infeasible to calculate the stream that generated a given digest, and it is computationally infeasible to generate a stream that will have a given digest.

Embodiments of the invention may employ a message digests and a hashing algorithm as described in IETF RFC 1321. This document, familiar to those skilled in the field of Internet communications, describes a hashing algorithm called Message Digest 5 or MD5. A characteristic of this algorithm is that its input space is evenly distributed across the digest space and therefore that there is a very small probability that two different files will generate the same digest. If the spaces were perfectly distributed then the probability that two different files have the same digest is 2¹²⁸ (which is approximately 3×10³⁸), so, practically, there is an infinitesimal chance that two files will ever generate the same digest and if two files have the same digest then there is an extremely high probability that the files are identical.

In preferred embodiments of the invention, a plurality of communication channels are established between a host peer and each target peer. For example, a channel may include a TCP/IP connection between the peers. In such embodiments, the one or more files are transmitted as discrete packets, the packets being sent on an available channel. This ensures that, in the event that there is a transmission delay on one channel (for example, due to a timeout period if a packet is lost), data can still be transmitted on the other channels, to make efficient use of communication bandwidth.

Typically, the packets of the last preceding paragraph are queued prior to transmission and are removed from the tail of a packet queue. More advantageously, there may be a plurality of packet queues, and packets are removed from the tails of a plurality of packet queues in turn. Each queue may be assigned a different priority. This can be achieved in embodiments in which packets are removed from the queues in a predetermined sequence such that the frequency at which packets are removed varies from one queue to another. Effectively, the greater the frequency from which packets are removed from a queue, the higher its priority.

From another aspect, the invention provides a network of computers in which files are transferred by a method embodying the first aspect of the invention.

From a further aspect, the invention provides a computer software product executable on a computer to enable that computer to transfer files by a method embodying the first aspect of the invention.

### BRIEF DESCRIPTION OF THE DRAWINGS

For a better understanding of the invention, reference is made to the drawings which are incorporated herein by reference, and in which:

FIG. 1 is a schematic diagram of a network comprising a plurality of interconnected peers each operating a method embodying the invention; and

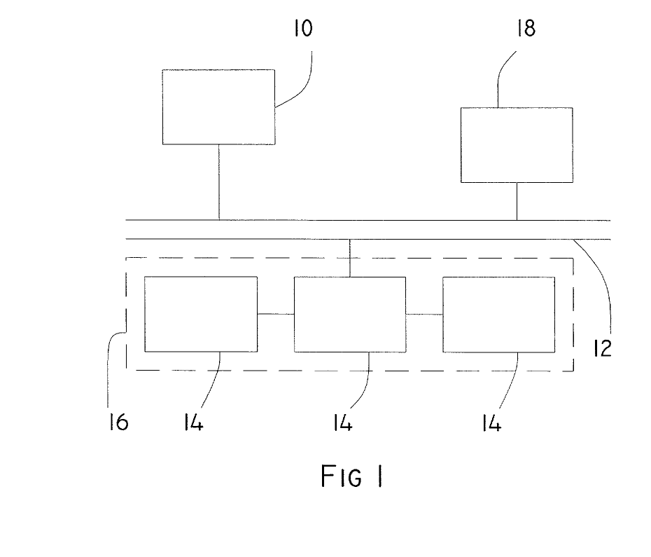

FIG. 2 is a simple block diagram of a communication server implemented as a software program executing on a peer computer.

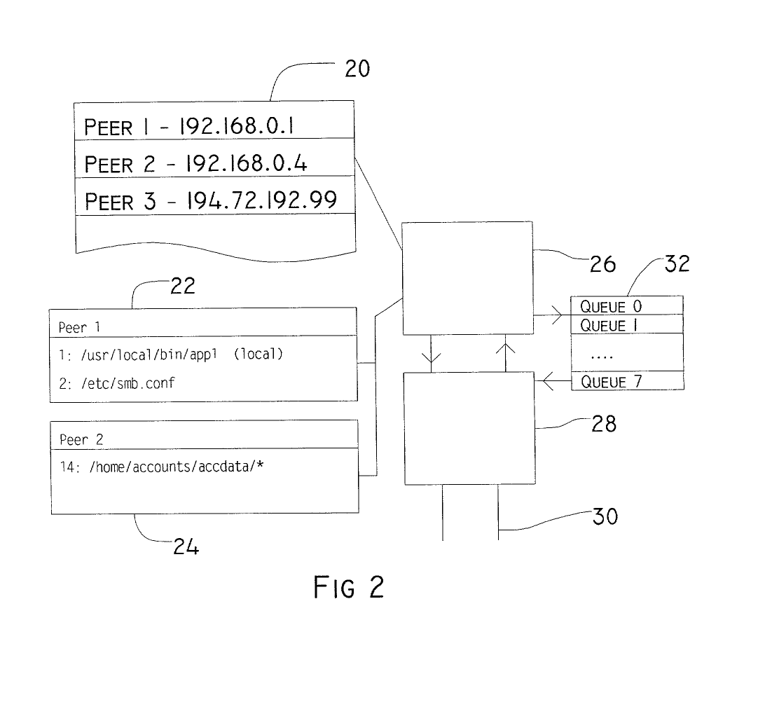

### DETAILED DESCRIPTION OF THE INVENTION

An embodiment of the invention is described below in detail, by way of example, and with reference to the accompanying drawings.

A network operating a method embodying the invention can comprise a diverse range of peers ranging, for example, form an embedded control computer to a large mainframe computer. These peers are interconnected by a diverse range of data carrying channels, including local-area networking apparatus and the Internet.

This example network comprises, a primary host peer 10 which is connected to a wide-area network (WAN) 12, such as the Internet. The network additionally comprises a group of target peers 14 interconnected in a local-area network 16. The local-area network 16 also has a connection to the WAN 12. Additionally, the network includes a peer 18 which is connected to the WAN 12.

Each peer in the network executes a software program referred to as a communication server. The communication server includes the following components:

a list of peers 20 that it can communicate with;

a list of tasks 22, 24 that must be done for each peer, called a worklist. There is a separate worklist for each entry in the list of peers;

a ‘task engine’ 26 that manages tasks in the worklist for the each peer;

a ‘packet engine’ 28 that sends and receives packets of data to and from remote peers through a network connection 30; and

a plurality of prioritised task queues 32 for storing pending transfer task requests.

When two peers connect the respective communication servers first exchange worklists so that each has the same list of tasks to complete and then they exchange data, modifying their worklists as they progress.

The control flow of the task engine will now be described.

A file transfer event is initiated when a user or a client application presents to the communication server on the local peer a request to transfer a file to another peer on the network. The request specifies:

the destination host name or address of a target peer;

the source and destination filenames;

the priority at which the task must be done; and

a sequence number of a single request that must be completed before this request is started, if such a prerequisite exists.

Before the request is processed further, the task engine calculates a message digest for the file that is to be transferred, and stores the calculated digest in memory along with details of the request. In this embodiment, the digest is calculated in accordance with the specification MD5 set forth in IETF document RFC 1321.

The communication server then checks that the request is not a duplicate of an earlier request, by proceeding as follows:

The server searches through the worklist for the target peer and looks for a file with an identical name.

a. If it finds a file with an identical name then it compares the digest stored in the worklist with the digest calculates for the current request.

i. If the digests are identical then the request is discarded and the user is informed.

ii. If the digests are different then the old task is discarded and replaced with the new task.

b. Otherwise the task is added to the worklist for the peer.

Tasks that are entered into a worklist have several properties, as follows:

each task in a worklist is numbered;

tasks generated locally on a peer are numbered sequentially from one; and

tasks that a peer receives from another peer are numbered from one and have a flag set in the task entry in the worklist to indicate that they were remotely generated.

The communication server then decides when it should connect to each peer for which it has tasks. This decision is made in dependence upon a set of user configurable parameters, including some or all of:

the minimum amount of time between connection attempts;

the number of retries for failed connection attempts and connection losses. After this number of instantaneous retries the system will wait for the time specified in the previous bullet before trying again;

the maximum number of connection attempts in a period;

the maximum connection time in a period; and

periods of the day during which connection attempts are prohibited.

When a connection is established between two peers, a number of communication channels are established. These will be used as multiple virtual streams to transfer data in parallel between the peers. In this embodiment, each channel is constituted by a TCP/IP connection between the peers.

Upon establishment of a connection between two peers, each sends the other the list of tasks that were created in the appropriate worklist since the last time the peers were connected.

When peers connect, each sends the other the highest sequence number of a remotely generated task that has been requested and is still outstanding. Upon receipt, the communication server on the remote peer compares this number with its own current highest sequence number of locally generated tasks and then calculates which tasks must be sent to the remote computer.

Once the local communication server knows the list of tasks that must be sent to the remote peer, it will start sending those tasks sequentially to the peer on the highest priority queue, (queue 0). (The queues and their prioritisation will be discussed in detail below.)

As each task is received the task engine decides whether to accept or reject the task. Specifically, when a peer receives a request to carry out a task, the communication server will check that it is not a duplicate request as follows:

it checks all the worklists from all the peers it communicates with and looks for a duplicate entry;

in a procedure similar to that described above with respect to the host peer, if it finds a request with an identical file name and a different digest it replaces that request;

if the request is new, the communication server checks the local filesystem. If a file of a corresponding name exists on the filesystem, it calculates the digest of the file on the filesystem and if the calculated digest is identical with that sored in the request, it will consider the task to be a duplicate.

If the task is a duplicate the communication server sends a reject message to the host peer and the request will be removed from the worklist of both peers.

As tasks are sent, the task engine updates its worklist as an acknowledgement for each sent task received. In particular, it deletes a task from the worklist if it has been rejected, and marks a task as accepted if it has been accepted.

In processing the task list, the communication server selects the first task to be done and puts it on an appropriate queue. Each task might include one of:

Sending or getting files

Making new directories

Deleting files or directories

Executing Scripts

As data packets are sent to the remote peer, the task engine gets progress reports that tell it that some portion of a file has been transferred. Transfer of data packets is handled by the packet engine, operation of which will be described in detail below. The task engine updates its worklist as each acknowledgement is received, so that it knows how much of the file has been transferred.

When a file has been fully transferred the peer that received the file acknowledges that the file has been accepted. The user or client application that requested the file to be transferred can ask that the acknowledgement happens in one of two ways:

as soon as the communication server of the target peer calculates the digest of the file it received and confirms that the calculated digest matches the stored digest in the worklist entry that caused the file to be transferred, it will send an acknowledgement of receipt; or

the file should not be accepted until some application on the target peer acknowledges that it has accepted it.

The acknowledgement sent by the target peer to the host peer is a copy of the file digest calculated by the target peer, digitally signed by the private key of the receiving peer. The sending peer can keep this acknowledgement as strong proof that the receiving peer did receive the content. When the acknowledgement has been received by the host peer the task is deleted from the worklist on both peers if, and only if, there are no tasks that refer to this task as a prerequisite. When the worklist is empty or when the time for the current connection runs out, the peers indicate that the session should be finished and close the connection.

Control flow for of the packet engine will now be described in detail.

The packet engine is responsible for transferring packets of data between peers. These packets can contain either task requests, as described above, or portions of files that are being transferred as the tasks are being performed.

When the connection is established, the task engine presents work to the packet engine. This work can include:

details of tasks being exchanged;

data being exchanged; or

responses to packets received.

The packet engine maintains several packet queues within which are stored packets waiting to be sent to a remote peer. The packet engine keeps an internal list of packets that should be transmitted on each queue. There is a separate list for each priority queue. A priority is assigned to each queue.

When the task engine transfers a packet to the packet engine for transmission, the packet engine places the packet on the tail of the internal list for the queue of appropriate priority.

During operation, the packet engine continually takes a packet from the head of a queue and puts it in any of the available channels for transmission to a remote peer. The packet engine takes a packet from each internal list, not in turn, but based on a programmed sequence that causes different amounts of bandwidth to be allocated to the different priority queues. The selection process operates as follows:

the packet engine builds a list of numbers, called the queue selection list. The entries in the list are the integers from 1 to 7 corresponding to seven of the priority queues (of course, this number may be different in other embodiments);

each integer appears a specific number of times in the queue selection list and in a specific order; and

the integers in the queue selection list are inserted so that the number 1 appears most often, number 2 next often and so on until the number 7 appears least often. The order is such that the instances of each given number are more or less equally spaced in the list. For example, the list may include the number 1 twenty times, down to the number 7 just one time, with the other numbers appearing a range of times between these extreme values. This might, for example, give a range of queue priorities from 33% for queue 1 to 2% for queue 7.

The packet engine decides which queue to send from as follows:

if there is a packet in queue 0 then place it on the next virtual channel;

get the next entry in the queue selection list and take a packet from the queue indicated and put it on the next virtual channel;

if there is no packet on the indicated queue then get the next entry in the queue selection list and put that on the next available virtual channel; and

repeat the above process until all queues are empty.

As the packet engine receives acknowledgement for each packet sent, it informs the task engine of the current status of that task.

Having thus described at least one illustrative embodiment of the invention, various alterations, modifications and improvements will readily occur to those skilled in the art.

Such alterations, modifications and improvements are intended to be within the scope and spirit of the invention. Accordingly, the foregoing description is by way of example only and is not intended as limiting. The invention's limit is defined only in the following claims and the equivalents thereto.

What is claimed is:

1. A method for transferring one or more files from a host peer to a target peer in which respective message digests are calculated for a file on a host peer and a target peer, and a comparison between the calculated digests is made in order to establish whether the target peer possesses the file in question.

2. A method according to claim 1 in which the comparison is made prior to transmission of a file from the host peer to the target peer.

3. A method according to claim 2 in which the comparison is made in the event that the target peer already possesses a file of the same name as that to be transferred.

4. A method according to claim 3 in which, in the event that the result of the comparison is that the calculated message digests are identical, the file is not transmitted by the host peer.

5. A method according to claim 1 in which comparison of message digests is made after a file has been sent to the target peer.

6. A method according to claim 5 in which, in the event that the result of the comparison is that the message digests differ, a file or part of a file is re-transmitted from the host peer to the target peer.

7. A method according to claim 1 in which the message digest is calculated by means of a hashing algorithm.

8. A method according to claim 7 in which the message digest is calculated by an algorithm that has an input space that is approximately evenly distributed over the digest space.

9. A method according to claim 7 in which the hashing algorithm is in accordance with specification MD5 as described in IETF RFC 1321.

10. A method according to claim 1 in which a plurality of communication channels are established between a host peer and each target peer.

11. A method according to claim 10 in which each channel includes a TCP/IP connection between the peers.

12. A method according to claim 10 in which the one or more files are transmitted as discrete packets, the packets being sent on an available channel.

13. A method according to claim 10 in which the packets are removed from the tail of a packet queue.

14. A method according to claim 10 in which packets are removed from the tails of a plurality of packet queues in turn.

15. A method according to claim 14 in which the frequency at which packets are removed from the queues in a predetermined sequence such that the frequency at which packets are removed varies from one queue to another.

16. A network of computers in which files are transferred by a method according to claim 1.

17. A computer software product executable on a computer to enable that computer to transfer files by a method according to claim 1.
